(19) United States
(12) Patent Application Publication
(10) Pub. No.: US 2017/0107638 A1
(43) Pub. Date: Apr. 20, 2017

(54) METHOD FOR FORMING MONOCRYSTALLINE SILICON INGOT AND WAFER

(71) Applicant: ZING SEMICONDUCTOR CORPORATION, Shanghai (CN)

(72) Inventors: DEYUAN XIAO, Shanghai (CN); RICHARD R. CHANG, Shanghai (CN)

(21) Appl. No.: 15/165,937

(22) Filed: May 26, 2016

(30) Foreign Application Priority Data
Oct. 15, 2015 (CN) 201510667035.5

(51) Int. Cl. C30B 15/20; C30B 33/00; C30B 30/04; C30B 15/30; C30B 29/06

(52) U.S. Cl. CPC C30B 15/203; C30B 15/30; C30B 29/06; C30B 30/04; C30B 33/00

(57) ABSTRACT

The present invention relates to a method for forming monocrystalline silicon ingot and wafer. When forming a monocrystalline silicon ingot, melted silicon is introduced with a gas comprising deuterium atoms to receive the deuterium atoms at interstice sites, and thus the oxygen, carbon and other impurity contained therein are decreased. When semiconductor devices are formed on wafers, which are formed by the silicon ingot, the deuterium atoms may be diffused out of the silicon wafer to bind to dangling bonds. Then, the structure of the silicon wafer is more stable and resistant to hot carriers, leakage current is lowered, and performance and reliability of the semiconductor devices are promoted.

### FIELD OF THE INVENTION

The present invention relates to a field of a single crystal grown by Czochralski method and semiconductor fabrication, and especially a method for forming ingot and wafer.

### BACKGROUND OF THE INVENTION

Monocrystalline silicon ingots, formed by Czochralski (CZ) method, a technology to grow cylindrical single crystal silicon, are served as basic materials for manufacturing semiconductor devices. The ingots are sliced, etched, cleaned, polished to form wafers.

According to the CZ method, polysilicon is heated to be melted in a crucible, a rod-like seed crystal, about 10 mm in diameter, is then soaked in the melted polysilicon. When the seed crystal is rotated and lifted gradually, the single crystal is grown with continued lattices by silicon atoms in the melted polysilicon. If the environment is stable, the crystallization is carried out stably, and then eventually, a monocrystalline silicon ingot, cylindrical single crystal silicon, is formed.

The melted polysilicon usually gets polluted in the quartz crucible. Oxygen atoms, one of the pollutants, penetrate into the lattices to a predetermined concentration, which depends on solubility of oxygen in silicon at a temperature of the melted polysilicon and real segregation co-efficient of oxygen in solid silicon. The concentration of the penetrated oxygen in the ingot is greater than the solubility of the oxygen in the solid silicon at a typical temperature in the fabrication process. The solubility of oxygen is decreased rapidly as the crystal is cooled, and then the solubility of oxygen is saturated in the ingot.

The ingot is then sliced into wafers. The interstitial oxygen atoms inside wafers form oxygen precipitations in the later thermal process. If these oxygen precipitations are located in an active region of semiconductor devices, the integrity of the gate oxide may be damaged and undesirable leakage current may be allowed.

### SUMMARY OF THE INVENTION

An object of the present invention is to provide a method for forming monocrystalline silicon ingot and wafer, through the method, oxygen and carbon impurities may be reduced and the performance of semiconductor devices formed afterwards may be promoted.

The present invention provides a method for forming monocrystalline silicon ingot, comprising steps of melting polysilicon fragments in a crucible with an introduction of a gas comprising deuterium atoms, and applying a magnetic field Czochralski method to form an ingot.

Additionally, in the method for forming monocrystalline silicon ingot, for example, the introduced gas may be deuterium gas, a mixture of deuterium gas and argon gas, and the like. The proportion of the deuterium gas and argon gas may be optional, such as 0.1%˜99%.

In the method for forming monocrystalline silicon ingot, the magnetic field Czochralski method may be exemplified by comprising steps of: melting the blended polysilicon fragments in the crucible at a predetermined temperature; pulling a seed crystal dipped into the melted polysilicon fragments with a predetermined pull rate to grow a single crystal, and slowing the pull rate to transit to a shoulder stage when a neck length of the single crystal reaching a predetermined length; maintaining a linear cooling rate with the slowed pull rate in the shoulder stage, forming a predetermined diameter for the ingot, and then transiting to a constant-diameter growth stage; and when the diameter of the ingot reaching the predetermined diameter, pulling the single crystal up rapidly with cooling but stopping linear cooling and lifting the crucible with a lifting rate, slowly adjusting the pull rate according to the diameter variety rate, and executing an automatic constant-diameter growth program to transit to an automatic constant-diameter growth stage after stabilizing the diameter of the ingot.

Further, in the method for forming monocrystalline silicon ingot, the diameter of the ingot may be optionally controlled through the pull rate and the predetermined temperature, and a magnetic field, such as 1000˜5000 Gauss, may be optionally generated.

According to the present invention, a method for forming monocrystalline silicon wafer is provided. An ingot which is formed according to the aforesaid method is utilized as a material to form a wafer, which is blended with deuterium atoms.

In the method for forming monocrystalline silicon wafer, further steps of slicing, grinding, polishing, surface profiling and cleaning may be comprised to turn the ingot into wafers.

The present invention may be beneficial to but not limited to: reducing the content of the oxygen, carbon atoms and other impurities blended during the Czochralski method for forming the ingot, resulted from the interstitial deuterium atoms, which comes from the introduced gas comprising deuterium atoms to the melted polysilicon fragments, in the ingot; strengthening the resistance to hot carriers, lowering leakage current, and promoting the performance and reliability of the semiconductor devices, resulted from the decreasing of the dangling bonds in that the interstitial deuterium atoms are diffused to bind to the dangling bonds in a process for forming the semiconductor devices.

### BRIEF DESCRIPTION OF THE DRAWINGS

Various objects and advantages of the present invention will be more readily understood from the following detailed description when read in conjunction with the appended drawing, in which:

FIG. 1 shows a flow chart of a method for forming monocrystalline silicon ingot according to an embodiment of the invention.

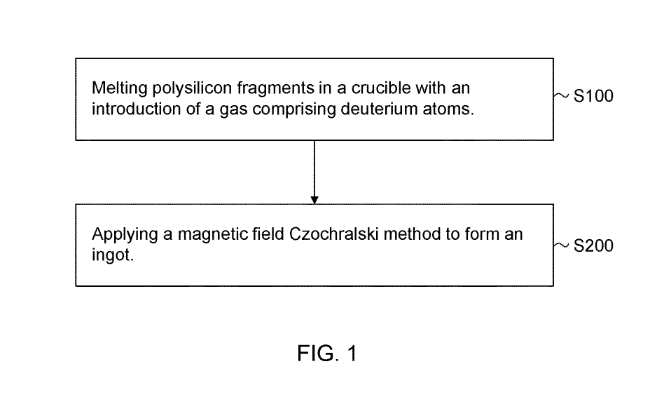

### DESCRIPTION OF EMBODIMENTS OF THE INVENTION

For a more complete understanding of the present disclosure and its advantages, reference is now made to the following description taken in conjunction with the accompanying drawings, in which like reference numbers indicate like features. Persons having ordinary skill in the art will understand other varieties for implementing example embodiments, including those described herein. The drawings are not limited to specific scale and similar reference numbers are used for representing similar elements. As used in the disclosures and the appended claims, the terms “example embodiment,” “exemplary embodiment,” and “present embodiment” do not necessarily refer to a single embodiment, although it may, and various example embodiments may be readily combined and interchanged, without departing from the scope or spirit of the present disclosure. Furthermore, the terminology as used herein is for the purpose of describing example embodiments only and is not intended to be a limitation of the disclosure. In this respect, as used herein, the term “in” may include “in” and “on”, and the terms “a”, “an” and “the” may include singular and plural references. Furthermore, as used herein, the term “by” may also mean “from”, depending on the context. Furthermore, as used herein, the term “if” may also mean “when” or “upon”, depending on the context. Furthermore, as used herein, the words “and/or” may refer to and encompass any and all possible combinations of one or more of the associated listed items.

According to an embodiment of the present invention, a method for forming monocrystalline silicon ingot is provided. The method comprises step S100: melting polysilicon fragments in a crucible with an introduction of a gas comprising deuterium atoms, and step S200: applying a magnetic field Czochralski method to form an ingot.

In the step S100, the polysilicon fragments may be chosen from polysilicon, n-type or p-type doped silicon wafers and the like. At first, the polysilicon fragments are positioned in the crucible to be melted to form an ingot afterwards and remove most impurities. Specifically, melting temperature and other details may be similar to those developed in the current technology, therefore here they are not repeated.

The gas introduced to the melted polysilicon fragments comprises deuterium atoms, and specifically, the gas may be pure deuterium gas or a mixture of deuterium gas and argon gas. If it is the later, the proportion of the deuterium gas and argon gas may be 0.1%˜99%, such as 50%; however, the proportion may be designed according to technical requirement, and it is not limited to the example.

The deuterium atoms are blended into the melted polysilicon fragments during the magnetic field Czochralski method for forming the ingot, and then received in the interstice sites in the ingot to reduce the content of the oxygen atoms and impurities to beneficial to promoting the performance of semiconductor devices formed later.

In the step S200, a magnetic field Czochralski method is applied to form the ingot. Specifically, the step S200 may comprise: melting the blended polysilicon fragments in the crucible at a predetermined temperature; pulling a seed crystal dipped into the melted polysilicon fragments with a predetermined pull rate to grow a single crystal, and slowing the pull rate to transit to a shoulder stage when a neck length of the single crystal reaching a predetermined length; maintaining a linear cooling rate with the slowed pull rate in the shoulder stage, forming a predetermined diameter for the ingot, and then transiting to a constant-diameter growth stage; and when the diameter of the ingot reaching the predetermined diameter, pulling the single crystal up rapidly with cooling but stopping linear cooling and lifting the crucible with a lifting rate, slowly adjusting the pull rate according to the diameter variety rate, and executing an automatic constant-diameter growth program to transit to an automatic constant-diameter growth stage after stabilizing the diameter of the ingot.

Further, the diameter of the ingot may be optionally controlled through the pull rate and the predetermined temperature, and designed according to process requirement. A magnetic field, such as 1000˜5000 Gauss, here 4600 Gauss, may be optionally generated in the step S200.

According to the present invention, a method for forming monocrystalline silicon wafer is further provided. An ingot which is formed according to the aforesaid method is utilized as a material to form a wafer, which is blended with deuterium atoms. Specifically, further steps of slicing, grinding, polishing, surface profiling and cleaning may be executed to turn the ingot into wafers.

Then, semiconductor devices may be formed on the wafer. Because of the deuterium atoms received in the interstice sites and the low content of the oxygen atoms and other impurities in the wafer, oxygen precipitations, which usually occur in a thermal process, may be significantly reduced to protect the integrity of gate oxide in a device active region and avoid from unnecessary leakage current.

To sum up, in the method for forming monocrystalline silicon ingot and wafer of the embodiment of the present invention may reduce the content of the oxygen atoms and other impurities blended during the Czochralski method for forming the ingot, resulted from the interstitial deuterium atoms, which comes from the introduced gas comprising deuterium atoms to the melted polysilicon fragments, in the ingot; strengthen the resistance to hot carriers, lower leakage current, and promote the performance and reliability of the semiconductor devices, resulted from the decreasing of the dangling bonds in that the interstitial deuterium atoms are diffused to bind to the dangling bonds in a process for forming the semiconductor devices.

While various embodiments in accordance with the disclosed principles have been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method for forming monocrystalline silicon ingot, comprising:
melting polysilicon fragments in a crucible with an introduction of a gas comprising deuterium atoms; and
applying a magnetic field Czochralski method to form an ingot.

2. The method for forming monocrystalline silicon ingot as claim 1, wherein the gas is deuterium gas.

3. The method for forming monocrystalline silicon ingot as claim 1, wherein the gas is a mixture of deuterium gas and argon gas.

4. The method for forming monocrystalline silicon ingot as claim 3, wherein a proportion of the deuterium gas and argon gas in the gas is within 0.1%˜99%.

5. The method for forming monocrystalline silicon ingot as claim 1, wherein the step of applying a magnetic field Czochralski method to form an ingot further comprises:
melting the polysilicon fragments blended with the gas in the crucible at a predetermined temperature;
pulling a seed crystal dipped into the melted polysilicon fragments with a predetermined pull rate to grow a single crystal, and slowing the pull rate to transit to a shoulder stage when a neck length of the single crystal reaching a predetermined length;
maintaining a linear cooling rate with the slowed pull rate in the shoulder stage, forming a predetermined diameter for the ingot, and then transiting to a constant-diameter growth stage; and
when the diameter of the ingot reaching the predetermined diameter, pulling the single crystal up rapidly with cooling but stopping linear cooling and lifting the crucible with a lifting rate, slowly adjusting the pull rate according to the diameter variety rate, and executing an automatic constant-diameter growth program to transit to an automatic constant-diameter growth stage after stabilizing the diameter of the ingot.

6. The method for forming monocrystalline silicon ingot as claim 5, wherein a diameter of the ingot is controlled through the pull rate and the predetermined temperature.

7. The method for forming monocrystalline silicon ingot as claim 5, wherein an intensity of a magnetic field utilized in the magnetic field Czochralski method is within 1000˜5000 Gauss.

8. A method for forming monocrystalline silicon wafer, wherein an ingot, which is formed according to the method, as claimed in claim 1 is utilized as a material to form a wafer which is blended with deuterium atoms.

9. The method for forming monocrystalline silicon wafer as claim 8, further comprising steps of executing slicing, grinding, polishing, surface profiling and cleaning to turn the ingot into the wafer.
